(19) United States
(12) Patent Application Publication
(10) Pub. No.: US 2012/0103475 A1
(43) Pub. Date: May 3, 2012

(54) METHOD OF MANUFACTURING METAL BASE PACKAGE WITH VIA

(75) Inventor: Kyoung-Min Kim, Seoul (KR)

(73) Assignee: WAVENICS INC., Daejeon (KR)

(21) Appl. No.: 13/139,746

(22) PCT Filed: Apr. 28, 2010
(86) PCT No.: PCT/KR2010/002665

§ 371 Date: Jun. 15, 2011

(51) Int. Cl. H05K 3/00

(52) U.S. Cl. 148/276

(57) ABSTRACT

A method of manufacturing a metal base package having a via structure that can provide via forming technology for a cheap 3D package and form a via having a high aspect ratio of various sizes is provided.

The method of manufacturing a metal base package having a via structure includes: preparing a metal substrate; forming an oxidation prevention mask pattern in the prepared metal substrate; forming a metal oxide layer by oxidizing a metal substrate portion that is exposed between the oxidation prevention mask patterns in a predetermined depth; removing the oxidation prevention mask pattern; forming a via forming mask pattern on the metal substrate and the metal oxide layer; forming a via in the metal oxide layer by performing chemical etching; removing the via forming mask pattern; and forming a conducting layer with a conductive material at the inside of the formed via.

### BACKGROUND OF THE INVENTION

(a) Field of the Invention

The present invention relates to a method of manufacturing a metal base package having a via structure. More particularly, the present invention relates to a method of manufacturing a metal base package having a via structure that can provide an interposer for three-dimensional (3D) package that can replace an expensive silicon interposer using a cheap chemical etching process because a metal oxide layer is formed in a metal substrate and a via having a high aspect ratio can be formed using characteristics of the metal oxide layer.

(b) Description of the Related Art

Nowadays, in a semiconductor manufacturing process, a great deal of effort has been made on developing a 3D integrated route for surpassing Moore's Law in order to seek continuous offensive scaling. For such technical development, supply networks of entire semiconductor industry such as an integrated device manufacturer (IDM), fabless semiconductor company, CMOS foundry, semiconductor assembly, and test outsourcing company, and a circuit assembly company are closely related. Moreover, 3D integration with through-silicon vias (3D-TSV) accelerates integration that is performed in CMOS wafer fab and movement to a fabless foundry model.

Furthermore, while passing an age of Moore's Law, in “Semicon West 2008”, which is a largest world semiconductor exhibition, industry leaders warn that down-size for down-size may not be practical and indicate that density improvement of a chip according to Moore's Law is not a technical problem but an economical problem. That is, industry leaders indicate that for down-size, much cost is requested, a geometry in a CMOS approaches an atom size that can no longer reduce, and but when further reducing a size, more power consumption, a more expensive device, and a slower operation may be caused. Therefore, nowadays, as a motion of trying to add a value to a semiconductor chip, a new manufacturing method for technology such as through-silicon via (TSV) for 3D package has been developed.

One of motives of 3D technical development is to obtain a smaller form factor with increased package density, and this is for improvement of a bandwidth, RF, and power consumption performance and cost reduction. Further, another motive for 3D technical development is a reliability problem, and systems having higher reliability are manufactured through vertical integration of some layers using a 3D stack wafer level optical device instead of a plastic implant molding lens module while using a 3D TSV instead of wire bonding or flip chip interconnect. Another factor is an effort of introducing new systems to a rough and space limited application environment such as automotive, bio, telecom, home appliances. For example, a wireless system-in-package (SiP) will be developed by combining different lithography nodes and different kinds of layers that are manufactured on a substrate of different materials such as Si, GaAs, and SiGe.

Further, a 3D wafer level package (WLP) incapsulation platform has been used for a production of a CMOS image sensor together with a via that pass to a rear surface of a wafer, will be extended to a power amplifier module, and a 3D TSV stack platform has been developed for a stacked memory and logic, and according to a trend to a via-first configuration, smaller vias approaching a diameter of 1 to 5 μm and 500-2,000 interconnects per chip are used.

In a real WLP access method, in order to couple ASIC and MEMS chips, some MEMS applications have already used a 3D interposer module platform, and the technical platform will be extended to many SiP applications, and in most cases, a silicon 3D interposer is used as a companion chip for a 3D integration system. An advantage of the 3D silicon interposer includes excellent intrinsic heat characteristics of a silicon package/substrate/board and size adjustment ability to an unlimited interconnect pitch, and uses engineering possibility such as passive device integration, cavity formation, and micro cooling channel construction for an economical heat management module, and 3D silicon interposeres are cheap and can be manufactured by an outsourcing company.

Further, TSV, which is 3D package technology is a package method of forming an electrode by forming a hole in a silicon wafer by replacing existing wire bonding and in a micro process of less than 40 nanometer, TSV has been spotlighted as an alternative that can solve a high speed input and output signal processing and extension of the quantity of signal channels (for example, increase the quantity of signal channels to 100 times) that cannot solve with wire bonding. When such TSV is applied, high frequency signal damage can be prevented, power consumption can be reduced by 70% or more, and a signal delay phenomenon can be reduced by 60% or more.

However, in TSV technology, in order to form a via, a dry etching process should be used, and in order to deeply form a via, a special masking operation is necessary and thus a production cost greatly increases, and much time is requested. Particularly, because a dry etching equipment (for example, induced coupled plasma (ICP)) requires an expensive cost of several billion won and uses a poisonous gas, a special exhaust device is required and a problem of environmental contamination exists.

Further, a silicon substrate is more expensive than a metal substrate such as an aluminum substrate.

Furthermore, because an advanced company holds most patents of TSV technology, a problem of patent conflict and a cost increase problem according to loyalty payment exist.

In a drilling method, which is a mechanical processing method, it is difficult to form a via having a size of minimum 100 μm or less and when directly processing each via one by one, much time and cost are requested.

Further, when forming a via with a general chemical etching method, isotropic etching is performed and thus an etching surface remains as ¼ circular shape (corner portion of an etched floor surface) and thus accuracy is deteriorated, and because an aspect ratio is very low, it is difficult to form a via and because undercut occurs by a depth that is etched under a mask surface, it is difficult to control a size of a via.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a method of manufacturing a metal base package having a via structure having advantages of forming a metal oxide layer in a metal substrate in order to provide via forming technology for a cheap 3D package and forming various sizes of via having a high aspect ratio using chemical vertical etching characteristics of a metal oxide layer.

An exemplary embodiment of the present invention provides a method of manufacturing a metal base package having a via structure, the method including: preparing a metal substrate; forming an oxidation prevention mask pattern in the prepared metal substrate; forming a metal oxide layer by oxidizing a metal substrate portion that is exposed between the oxidation prevention mask pattern in a predetermined depth; removing the oxidation prevention mask pattern; forming a via forming mask pattern on the metal substrate and the metal oxide layer; forming a via in the metal oxide layer by performing chemical etching; removing the via forming mask pattern; and forming a conducting layer with a conductive material at the inside of the formed via.

A process of forming a conducting layer can be embodied using a plating method or a silk screen method.

Before forming the conducting layer, a process of filling a pore of the inside of the via may be further performed.

After forming the conducting layer, a process of forming a solder ball to be connected to the conducting layer of a via may be further performed.

After forming the conducting layer, a redistribution may be formed to be connected to the conducting layer of a via.

According to a method of manufacturing a metal base package having a via structure according to an exemplary embodiment of the present invention, because a via is formed using a metal oxide layer having vertical etching characteristics when performing chemical etching, there is no undercut and a via having a high aspect ratio (wall surface approaching vertical) can be formed.

According to a method of manufacturing a metal base package having a via structure according to an exemplary embodiment of the present invention, a metal substrate cheaper than a silicon substrate is used, and a via is formed using a chemical etching process requiring a relative cheap cost and having a short process time and thus a high price competitive power can be obtained.

In a chemical etching process using in a method of manufacturing a metal base package having a via structure according to an exemplary embodiment of the present invention, an equipment much cheaper than that using in a TSV process is used and a poisonous gas may not be used and thus a special exhaust apparatus is unnecessary or an environment contamination problem does not exist.

According to a method of manufacturing a metal base package having a via structure according to an exemplary embodiment of the present invention, a metal oxide layer has excellent high frequency characteristics, compared with a silicon substrate and thus the metal oxide layer has high signal transmission characteristics and thus reliability is greatly improved.

According to a method of manufacturing a metal base package having a via structure according to an exemplary embodiment of the present invention, a mixing phenomenon of a signal can be greatly lowered with high signal separation characteristics of a metal oxide layer.

According to a method of manufacturing a metal base package having a via structure according to an exemplary embodiment of the present invention, a conductive wire can be formed in one surface with a cheap process cost without depositing a separate metal material using a metal substrate. However, in a conventional silicon substrate, in order to form a wiring, a metal material should be deposited in an upper surface and a lower surface.

According to a method of manufacturing a metal base package having a via structure according to an exemplary embodiment of the present invention, technology of a new concept that can replace a silicon interposer for 3D package can be provided, and new technology having no conflict problem with conventional patent can be provided.

Further, according to a method of manufacturing a metal base package having a via structure according to an exemplary embodiment of the present invention, because a via is formed by performing chemical etching using a masking method of a semiconductor manufacturing process, a via of a fine size can be formed in a unit of several μm.

### BRIEF DESCRIPTION OF THE DRAWINGS

FIG. 1 is a diagram illustrating a process of a method of manufacturing a metal base package having a via structure according to a first exemplary embodiment of the present invention.

FIG. 2 is a flowchart illustrating a method of manufacturing a metal base package having a via structure according to a first exemplary embodiment of the present invention.

FIG. 3 is a cross-sectional view illustrating a transverse cross-section of a via structure in a method of manufacturing a metal base package having a via structure according to a first exemplary embodiment of the present invention.

FIG. 4 is a diagram illustrating a process of another exemplary embodiment of a height adjustment step in a method of manufacturing a metal base package having a via structure according to a first exemplary embodiment of the present invention.

FIG. 5 is a diagram illustrating a process of a method of manufacturing a metal base package having a via structure according to a second exemplary embodiment of the present invention.

FIG. 6 is a diagram illustrating a process of a method of manufacturing a metal base package having a via structure according to a third exemplary embodiment of the present invention.

FIG. 7 is a diagram illustrating a process of a method of manufacturing a metal base package having a via structure according to a fourth exemplary embodiment of the present invention.

FIG. 8 is a diagram illustrating a process of a method of manufacturing a metal base package having a via structure according to a fifth exemplary embodiment of the present invention.

FIG. 9 is a diagram illustrating a process of a method of manufacturing a metal base package having a via structure according to a sixth exemplary embodiment of the present invention.

FIG. 10 is a diagram illustrating a process of a method of manufacturing a metal base package having a via structure according to a seventh exemplary embodiment of the present invention.

FIG. 11 is a cross-sectional view illustrating an example of a metal base package having a via structure that is manufactured using a method of manufacturing a metal base package having a via structure according to a seventh exemplary embodiment of the present invention.

FIG. 12 is a top plan view illustrating an example of a metal base package having a via structure that is manufactured using a method of manufacturing a metal base package having a via structure according to a seventh exemplary embodiment of the present invention.

FIG. 13 is a diagram illustrating a process of a method of manufacturing a metal base package having a via structure according to an eighth exemplary embodiment of the present invention.

FIG. 14 is a diagram illustrating a process of a method of manufacturing a metal base package having a via structure according to a ninth exemplary embodiment of the present invention.

FIG. 15 is a diagram illustrating a process of a method of manufacturing a metal base package having a via structure according to a tenth exemplary embodiment of the present invention.

FIG. 16 is a diagram illustrating a process using a solder ball of an LGA form in a method of manufacturing a metal base package having a via structure according to a tenth exemplary embodiment of the present invention.

FIG. 17 is a diagram illustrating a process of a method of manufacturing a metal base package having a via structure according to an eleventh exemplary embodiment of the present invention.

### DETAILED DESCRIPTION OF THE EMBODIMENTS

Exemplary embodiments of a method of manufacturing a metal base package having a via structure according to the present invention will be described in detail with reference to the drawings. As those skilled in the art would realize, the described embodiments may be modified in various different ways, all without departing from the spirit or scope of the present invention. The present invention will be described more fully hereinafter with reference to the accompanying drawings, in which exemplary embodiments of the invention are shown. Further, in the drawings, a size and thickness of each element are randomly represented for better understanding and ease of description, and the present invention is not limited thereto. Like reference numerals designate like elements throughout the specification. The drawings and description are to be regarded as illustrative in nature and not restrictive.

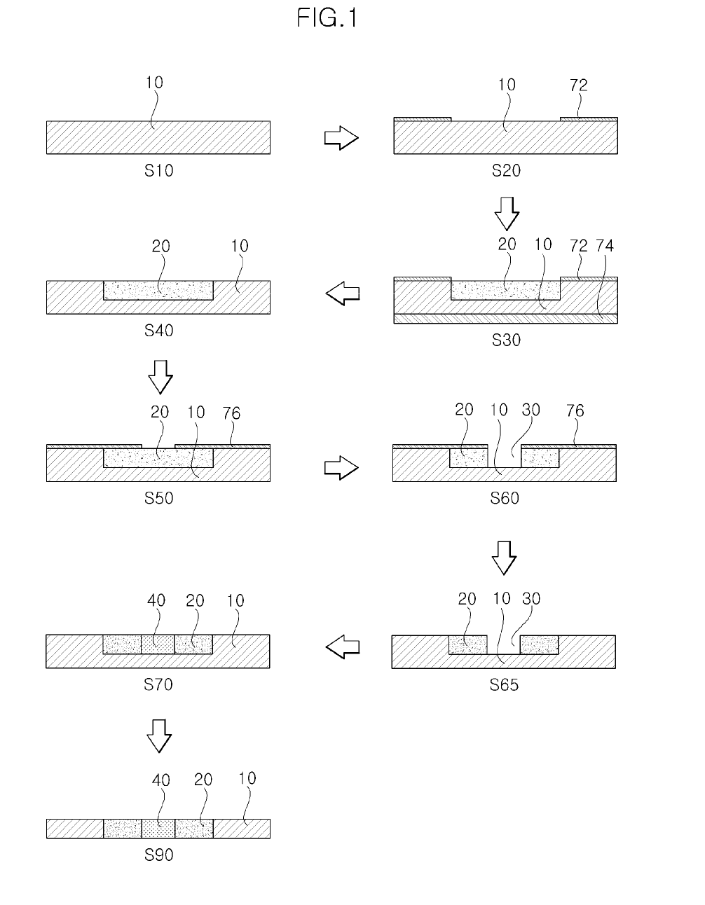

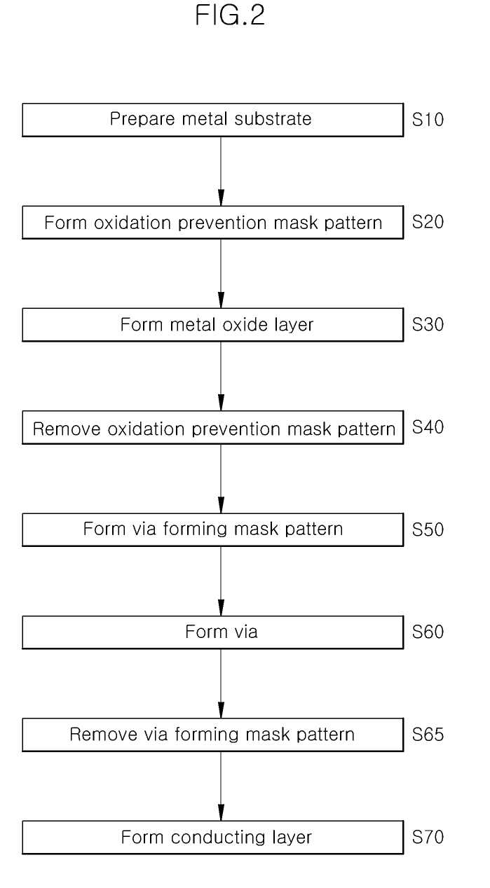

First, as shown in FIGS. 1 and 2, a method of manufacturing a metal base package having a via structure according to a first exemplary embodiment of the present invention includes substrate preparation step S10, oxidation pattern forming step S20, oxidation step S30, oxidation pattern removal step S40, via pattern forming step S50, via forming step S60, via pattern removal step S65, and conducting step S70.

At the substrate preparation step S10, a metal substrate 10 is prepared.

As the metal substrate 10, various conductive metals that can perform oxidation (for example, anodization) such as aluminum (Al), magnesium (Mg), and titanium (Ti) can be used.

At the oxidation pattern forming step S20, an oxidation prevention mask pattern 72 is formed in the prepared metal substrate 10.

The oxidation prevention mask pattern 72 is formed in one surface (for example, an upper surface) of the metal substrate 10 in order to expose a portion to form a metal oxide layer 20.

The other surface (for example, a lower surface) of the metal substrate 10 is protected by covering to prevent oxidation using an electrode 74.

The electrode 74 is used for performing anodization.

A separate oxidation barrier layer (not shown) instead of the electrode 74 may be formed in the other surface of the metal substrate 10.

At the oxidation step S30, by oxidizing a portion of the metal substrate 10 that is exposed between the oxidation prevention mask pattern 72 in a predetermined depth, the metal oxide layer 20 is formed.

The metal substrate 10 is oxidized using anodization.

At the oxidation pattern removal step S40, the oxidation prevention mask pattern 72 is removed.

At the via pattern forming step S50, a via forming mask pattern 76 is formed on the metal substrate 10 and the metal oxide layer 20.

The via forming mask pattern 76 is formed to expose the metal oxide layer 20 of a portion in which a via 30 is to be formed.

At the via forming step S60, the via 30 is formed in the metal oxide layer 20 by performing chemical etching.

When chemical etching is performed in the metal oxide layer 20, etching is performed in a form having a very large aspect ratio in a vertical direction by characteristics of the metal oxide layer 20, and the via 30 is formed in a shape of an almost vertical wall surface.

The via 30 is formed in a form having no undercut even in an upper end portion.

Further, when etching the metal oxide layer 20 using a chemical etching method, an etched depth can be easily controlled, and the via 30 having a size of several μm unit may be formed according to a precision degree of the via forming mask pattern 76.

At the via pattern removal step S65, the via forming mask pattern 76 is removed.

At the conducting step S70, a conducting layer 40 is formed by performing plating with a conductive material in an inner surface of the via 30 that is formed in the metal oxide layer 20.

At the conducting step S70, before forming the conducting layer 40, a process of filling a surface of the metal oxide layer 20 or a pore of an inner surface of the via 30 may be further performed, as needed.

The surface of the metal oxide layer 20 or the pore of the inner surface of the via 30 can be filled with sealing using an organic material.

At the conducting step S70, the conducting layer 40 is well formed with plating without using a seed and thus a plating operation is very simply performed.

The conducting step S70 is not shown in the drawing, but the conducting layer 40 may be formed by filling the inside of the via 30 with a conductive material using a silk screen method in addition to the plating method.

As described above, after the conducting layer 40 is formed, height adjustment step S90 of removing a lower end portion of the metal substrate 10 may be further performed to correspond to a thickness of the metal oxide layer 20.

At the height adjustment step S90, a lower end portion of the metal substrate 10 is removed with a method of etching or lapping.

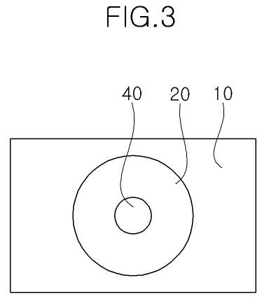

As shown in FIG. 3, a via structure that is formed as described above may be formed with the conducting layer 40 and the via 30 of a quasi-coaxial type.

A via structure according to an exemplary embodiment of the present invention can be formed in various forms and shapes in addition to a quasi-coaxial type.

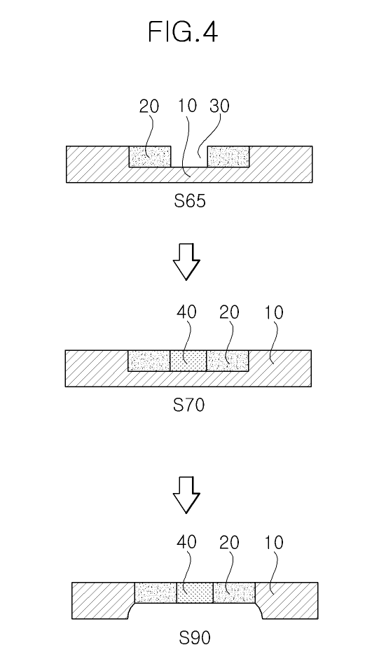

As shown in FIG. 4, at the height adjustment step S90, only a portion of a peripheral metal substrate 10 of a portion in which the metal oxide layer 20 is formed or a portion in which the via 30 is formed may be partially removed without removing an entire surface of a lower end portion of the metal substrate 10.

As described above, a solder ball can be installed in a lower surface of the via 30 and the plating layer 40 that are exposed by performing height adjustment step S90.

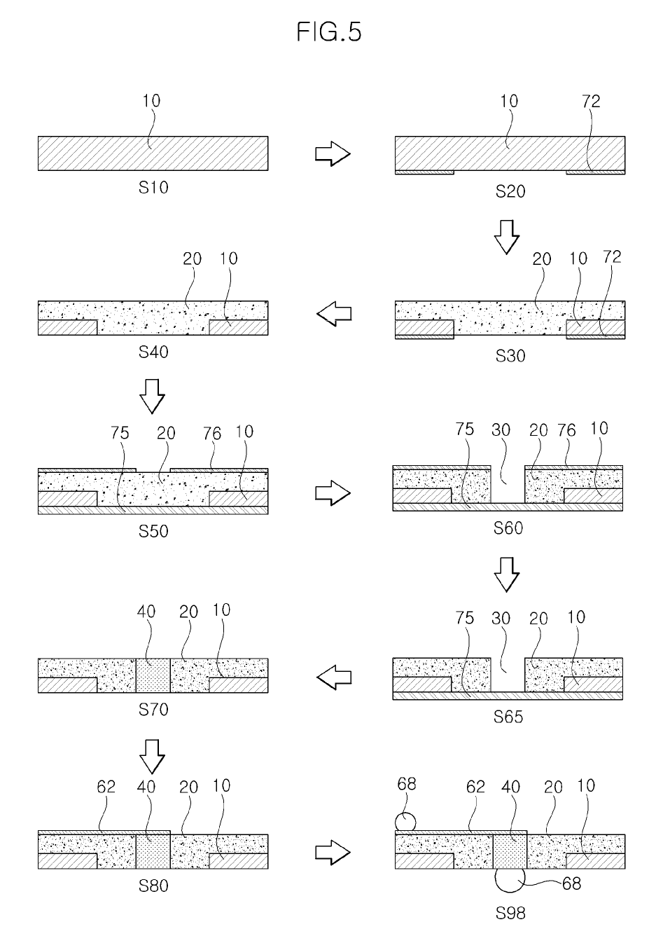

As described in FIG. 5, a method of manufacturing a metal base package module having a via structure according to a second exemplary embodiment of the present invention includes substrate preparation step S10, oxidation pattern forming step S20, oxidation step S30, oxidation pattern removal step S40, via pattern forming step S50, via forming step S60, via pattern removal step S65, conducting step S70, upper electrode forming step S80, and soldering step S98.

In the second exemplary embodiment, a detailed description of processes identical to or corresponding to those of the first exemplary embodiment will be omitted.

At the oxidation pattern forming step S20, the oxidation prevention mask pattern 72 is formed in a lower surface of the prepared metal substrate 10.

As described above, in a state where the oxidation prevention mask pattern 72 is formed in a lower surface of the metal substrate 10, when the oxidation step S30 is performed, oxidizing is performed in a portion of a lower surface of the metal substrate 10 and an entire upper surface of the metal substrate 10 that are exposed between the oxidation prevention mask pattern 72 and thus the metal oxide layer 20 is formed in two stages.

An oxidation barrier layer (not shown) may be formed over an entire upper surface of the metal substrate 10.

At the via pattern forming step S50, the via forming mask pattern 76 is formed on the metal oxide layer 20 that is formed at an upper surface side of the metal substrate 10, and a metal plate 75 is installed at a lower surface side of the metal substrate 10.

At the via forming step S60, the via 30 is penetrated in the metal oxide layer 20 that is formed in two stages by performing chemical etching. In this case, by installing the metal plate 75 at a lower surface side of the metal substrate 10, chemical etching can be performed to effectively penetrate the metal oxide layer 20.

At the pore removal step S65, before performing plating or a silk screen at the conducting step S70, operation of filling a pore of an inner surface of the via 30 or a surface of the metal oxide layer 20 with an organic material is performed, as needed.

At the upper electrode forming step S80, a redistribution 62 that is connected to the conducting layer 40 is formed in an upper surface of the metal oxide layer 20.

At the soldering step S98, a solder ball 68 is installed to be connected to the conducting layer 40 and the redistribution 62 that are exposed to an upper surface and a lower surface of the metal oxide layer 20.

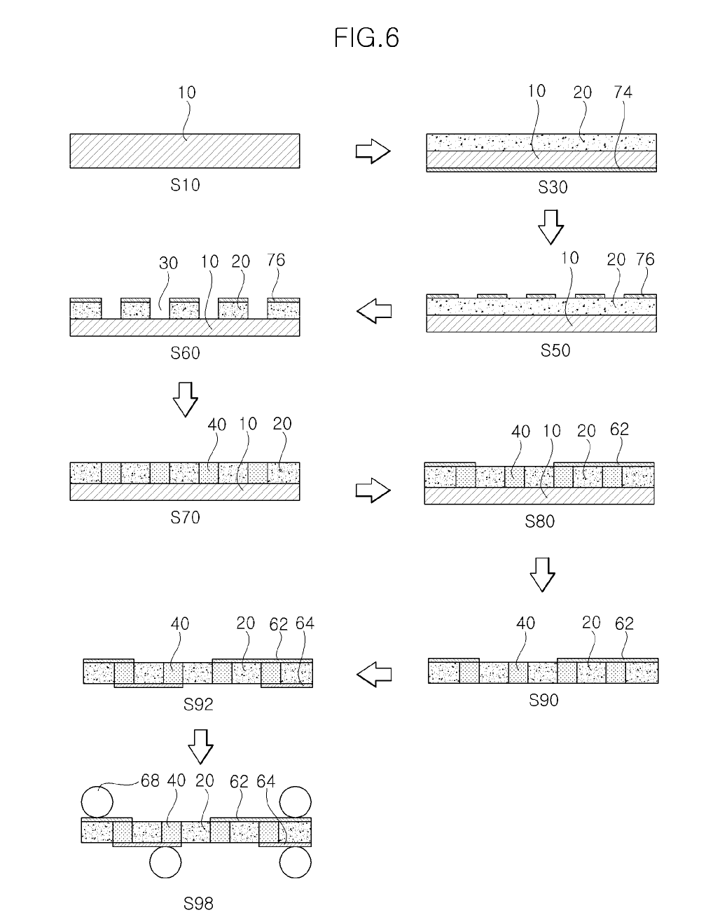

As shown in FIG. 6, a method of manufacturing a metal base package module having a via structure according to a third exemplary embodiment of the present invention includes substrate preparation step S10, oxidation step S30, via pattern forming step S50, via forming step S60, conducting step S70, upper electrode forming step S80, height adjustment step S90, lower electrode forming step S92, and soldering step S98.

In the third exemplary embodiment, a detailed description of processes identical to or corresponding to those of the first exemplary embodiment and the second exemplary embodiment will be omitted.

The oxidation step S30 performs anodization in a state of protecting a lower surface of the metal substrate 10 as the electrode 74 without forming a separate oxidation prevention mask pattern 72.

As described above, when performing oxidation in a state of protecting a lower surface of the metal substrate 10 as the electrode 74, oxidation is performed in an entire upper surface of the metal substrate 10 and thus the metal oxide layer 20 is formed.

At the via pattern forming step S50, the via forming mask pattern 76 is formed on the metal oxide layer 20 that is formed at an upper surface side of the metal substrate 10.

At the height adjustment step S90, lapping or etching of the metal substrate 10 is performed to expose a lower surface of the metal oxide layer 20 by removing all the metal substrates 10 of the lower surface.

At the lower electrode forming step S92, a redistribution 64 that is connected to the conducting layer 40 is formed in the lower surface of the metal oxide layer 20, as in the upper electrode forming step S85.

At the soldering step S98, the solder ball 68 is installed to be connected to the conducting layer 40 and redistributions 62 and 64 that are exposed to an upper surface and a lower surface of the metal oxide layer 20.

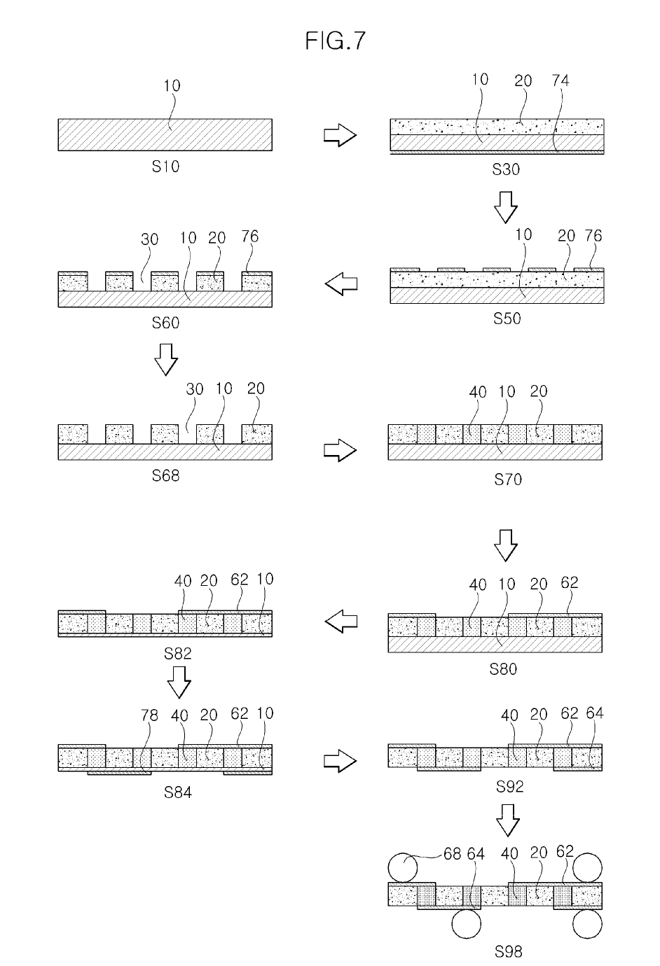

As shown in FIG. 7, a method of manufacturing a metal base package module having a via structure according to a fourth exemplary embodiment of the present invention includes substrate preparation step S10, oxidation step S30, via pattern forming step S50, via forming step S60, conducting step S70, upper electrode forming step S80, height adjustment step S82, electrode mask pattern step S84, lower electrode forming step S92, and soldering step S98.

In the fourth exemplary embodiment, a detailed description of processes identical to or corresponding to those of the first exemplary embodiment to the third exemplary embodiment will be omitted.

Particularly, in the fourth exemplary embodiment, a process similar to the third exemplary embodiment is performed.

At the height adjustment step S82, lapping or etching is performed so that the metal substrate 10 remains in a predetermined thickness without removing all the metal substrate 10 of a lower surface (thickness to be formed as an electrode).

At the electrode mask pattern step S84, an electrode mask pattern 78 is formed in a lower surface of the metal substrate 10 in a pattern (for example, a pattern that conceals the metal substrate 10 of a portion in which the redistribution 64 of a lower surface is to be formed) corresponding to a pattern of the redistribution 64 of a lower surface.

At the lower electrode forming step S92, the metal substrate 10 is partially removed to expose the metal oxide layer 20 of a portion in which the electrode mask pattern 78 is not formed.

As described above, when partially removing the metal substrate 10, a remaining portion of the metal substrate 10 is formed as the redistribution 64 of a lower surface.

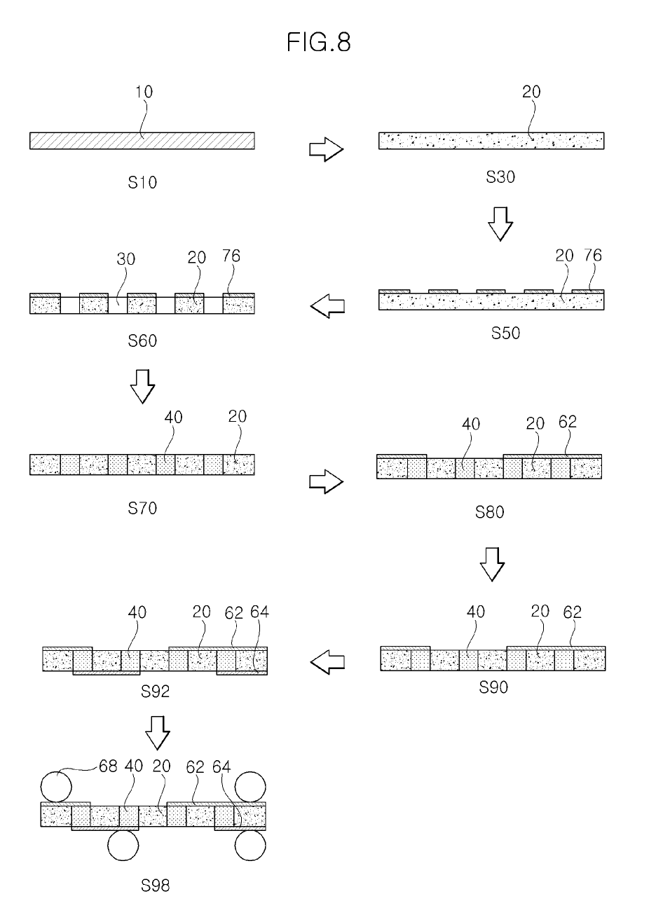

As shown in FIG. 8, a method of manufacturing a metal base package module having a via structure according to a fifth exemplary embodiment of the present invention includes substrate preparation step S10, oxidation step S30, via pattern forming step S50, via forming step S60, conducting step S70, upper electrode forming step S80, lower electrode forming step S92, and soldering step S98.

In the fifth exemplary embodiment, a detailed description of processes identical to or corresponding to those of the first exemplary embodiment to the fourth exemplary embodiment will be omitted.

At the oxidation step 30, oxidation is performed in an entire height of the metal substrate 10.

As described above, when the metal oxide layer 20 is formed by performing oxidation in an entire height of the metal substrate 10, it is unnecessary to separately perform height adjustment step S90.

In the fifth exemplary embodiment, processes, except for the above-described process can be performed with processes similar to the third exemplary embodiment and therefore a detailed description thereof will be omitted.

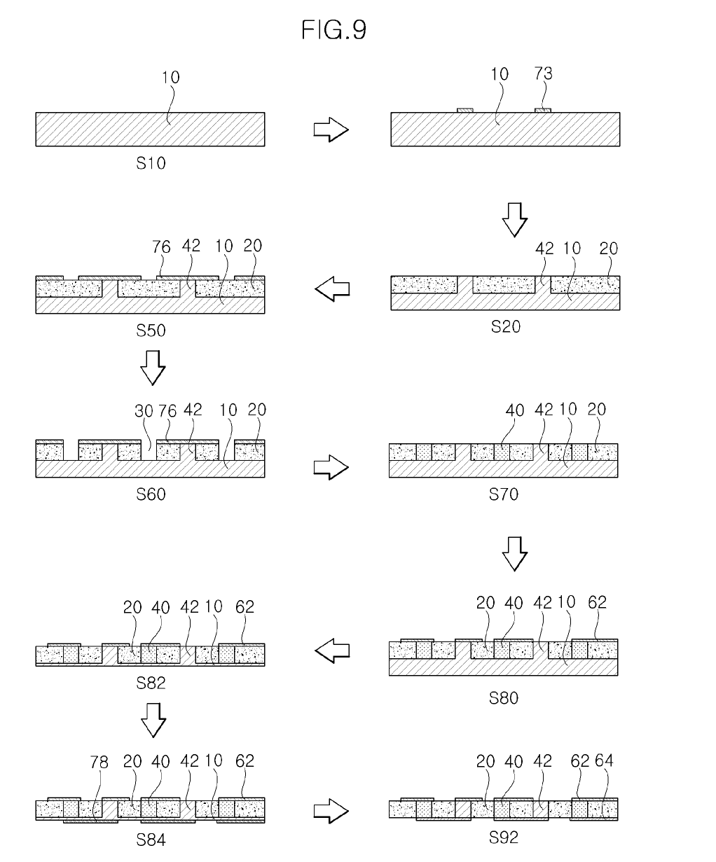

As shown in FIG. 9, a method of manufacturing a metal base package module having a via structure according to a sixth exemplary embodiment of the present invention includes substrate preparation step S10, oxidation pattern forming step S20, oxidation step S30, via pattern forming step S50, via forming step S60, conducting step S70, upper electrode forming step S80, height adjustment step S82, electrode mask pattern step S84, and lower electrode forming step S92.

In the sixth exemplary embodiment, a detailed description of processes identical to or corresponding to those of the first exemplary embodiment to the fifth exemplary embodiment will be omitted.

At the oxidation pattern forming step S20, an oxidation prevention mask pattern 73 is formed to conceal a portion to use as a portion of a via structure in the metal substrate 10.

As described above, when the oxidation prevention mask pattern 73 is formed and oxidation step S30 is performed, a portion of the metal substrate 10 that is not naturally oxidized is formed as a via structure and thus a via electrode 42 that can be conducted is formed. That is, a via structure can be formed with only an oxidizing process.

At the upper electrode forming step S90 and the lower electrode forming step S92, the redistribution 62 of an upper surface and the redistribution 64 of a lower surface are formed to electrically connect the via electrode 42 and the conducting layer 40 that are formed as described above.

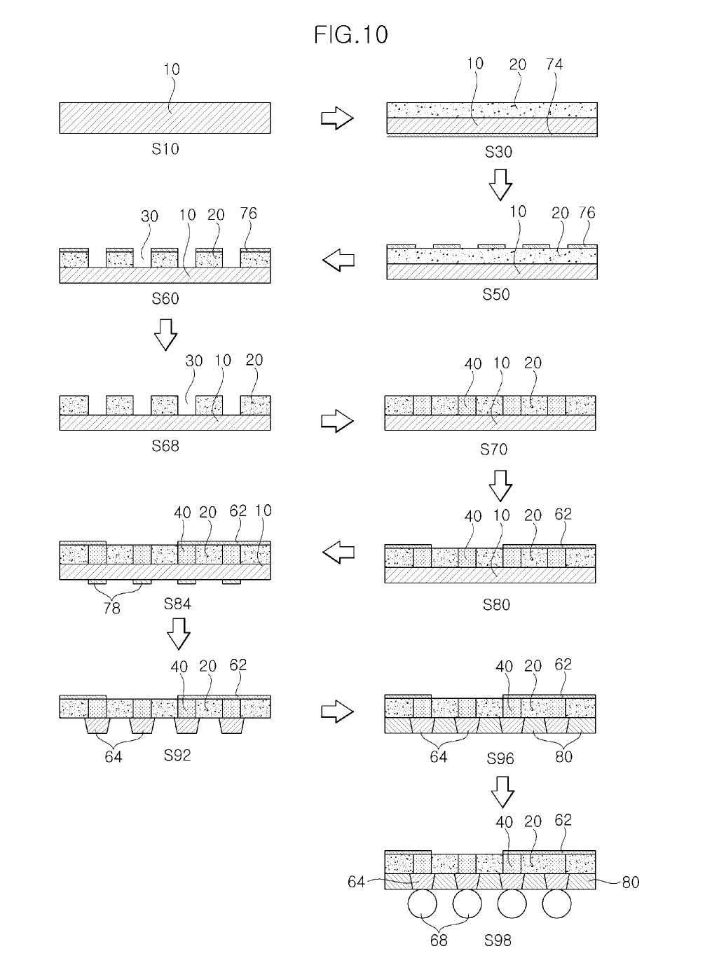

As shown in FIG. 10, a method of manufacturing a metal base package module having a via structure according to a seventh exemplary embodiment of the present invention includes substrate preparation step S10, oxidation step S30, via pattern forming step S50, via forming step S60, conducting step S70, upper electrode forming step S80, electrode mask pattern step S84, lower electrode forming step S92, insulation layer forming step S96, and soldering step S98.

In the seventh exemplary embodiment, a detailed description of processes identical to or corresponding to those of the first exemplary embodiment to the sixth exemplary embodiment will be omitted.

Particularly, in the seventh exemplary embodiment, a process similar to that of the fourth exemplary embodiment is performed.

After an upper electrode 62 is formed, height adjustment step S82 of adjusting a height of the metal substrate 10 of a lower surface is performed, and electrode mask pattern step S84 may be performed.

At the electrode mask pattern step S84, the electrode mask pattern 78 is formed to prevent the metal substrate 10 of a portion in which the conducting layer 40 is formed from being etched.

As described above, when the electrode mask pattern 78 is formed, if lower electrode forming step S92 is performed by performing etching, only a portion in which the conducting layer 40 is formed remains in the metal substrate 10 and thus a lower electrode 64 is formed.

At the insulation layer forming step S96, in order to prevent short circuit between the lower electrodes 64, by filling an insulation material in a portion in which the metal substrate 10 is removed, an insulation layer 80 is formed.

As an insulation material for forming the insulation layer 80, a polymer material or an organic material such as EMC may be used.

When the insulation layer 80 is formed as described above, mechanical strength can be improved.

The insulation layer forming step S96 may be omitted, as needed.

At the soldering step S98, the solder ball 68 is installed in a portion in which the lower electrode 64 is formed.

After the via forming step S60 and the conducting step S70 are performed, electrode mask pattern step S84, lower electrode forming step S92, and insulation layer forming step S96 are sequentially performed and a process may be performed in order of upper electrode forming step S80 and soldering step S98.

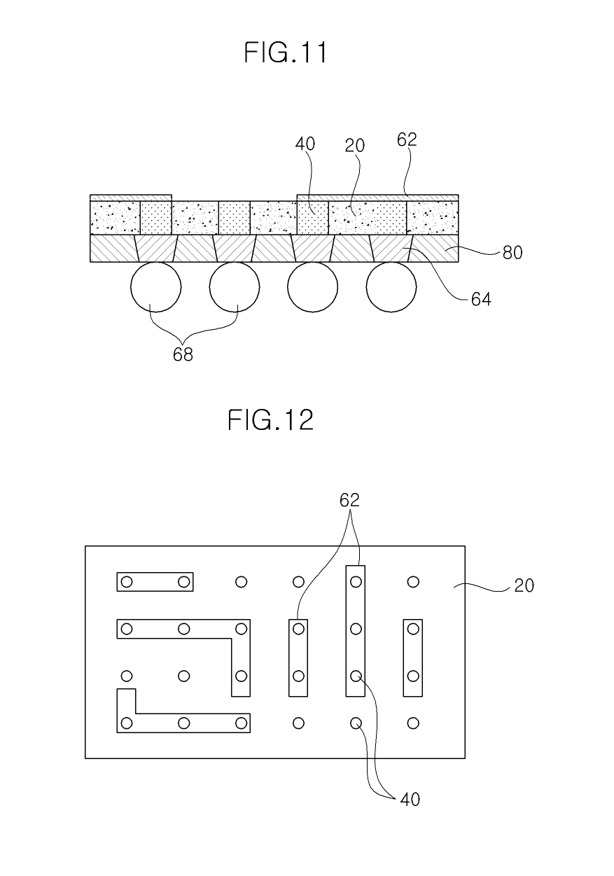

FIG. 11 is a cross-sectional view illustrating a metal base package module having a via structure according to an exemplary embodiment of the present invention that is manufactured through the above process, and FIG. 12 is a top plan view illustrating a metal base package module having a via structure according to an exemplary embodiment of the present invention.

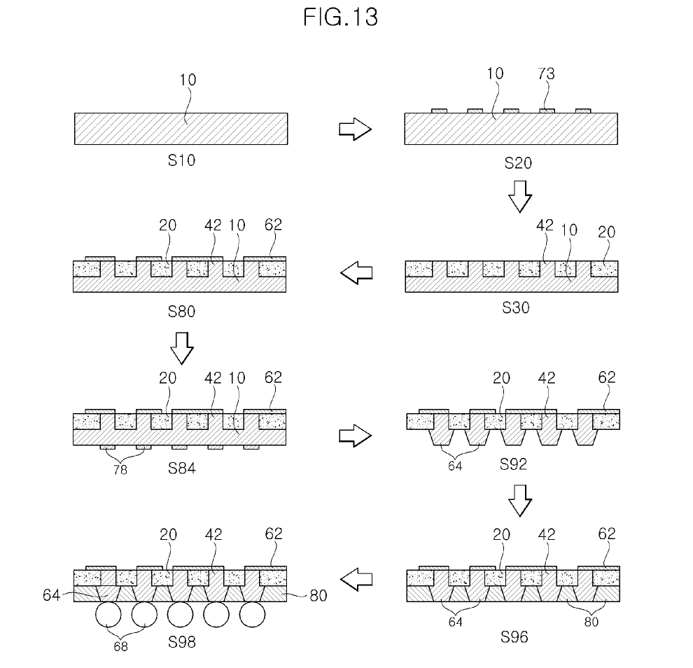

As shown in FIG. 13, a method of manufacturing a metal base package module having a via structure according to an eighth exemplary embodiment of the present invention includes substrate preparation step S10, oxidation pattern forming step S20, oxidation step S30, upper electrode forming step S80, electrode mask pattern step S84, lower electrode forming step S92, insulation layer forming step S96, and soldering step S98.

In the eighth exemplary embodiment, a detailed description of processes identical to or corresponding to those of the first exemplary embodiment to the seventh exemplary embodiment will be omitted.

At the oxidation pattern forming step S20, when forming the oxidation prevention mask pattern 73 to conceal a portion to use as a portion of a via structure in the metal substrate 10 and performing the oxidation step S30, a portion of the metal substrate 10 that is not naturally oxidized is formed as a via structure and thus the via electrode 42 that can be conducted is formed.

The following process can be performed with the same process as that of the seventh exemplary embodiment.

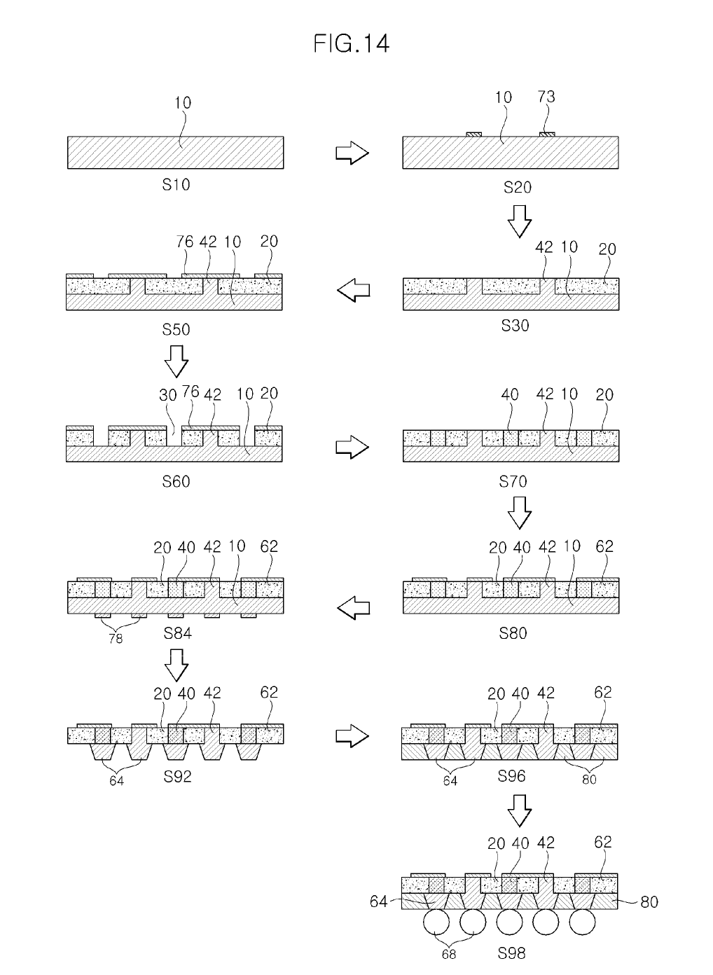

As shown in FIG. 14, a method of manufacturing a metal base package module having a via structure according to a ninth exemplary embodiment of the present invention includes substrate preparation step S10, oxidation pattern forming step S20, oxidation step S30, via pattern forming step S50, via forming step S60, conducting step S70, upper electrode forming step S80, electrode mask pattern step S84, lower electrode forming step S92, insulation layer forming step S96, and soldering step S98.

The ninth exemplary embodiment can be performed with a combination of processes of the sixth exemplary embodiment and the seventh exemplary embodiment and therefore a detailed description thereof will be omitted.

In the seventh exemplary embodiment to the ninth exemplary embodiment, a method of forming the via electrode 42 through the oxidation pattern forming step S20 and the oxidation step S30 does not receive a large limitation in a size of the via electrode 42 but is advantageous in forming in a relative large size, and a method of forming the conducting layer 40 through the via pattern forming step S50 and the via forming step S60 is advantageous in forming in a relative small size and thus it is preferable in view of a production cost and productivity to appropriately select and use or to combine and use the oxidation pattern forming step S20, the oxidation step S30, the via pattern forming step S50, and the via forming step S60, as needed.

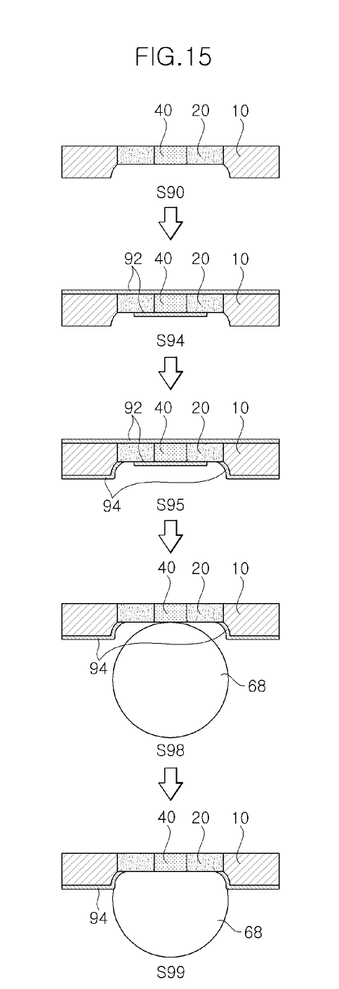

As shown in FIG. 15, in a method of manufacturing a metal base package module having a via structure according to a tenth exemplary embodiment of the present invention, at the height adjustment step S90, after partially removing only a portion of the peripheral metal substrate 10 of a portion in which the metal oxide layer 20 is formed or a portion in which the via 30 is formed without removing an entire surface of a lower end portion of the metal substrate 10 (see FIG. 4), insulation pattern forming step S94, oxidation insulation step S95, soldering step S98, and reflow step S99 are sequentially further performed.

At the insulation pattern forming step S94, an oxidation barrier layer 92 is formed in a portion of the via electrode 42 or the conducting layer 40 of a lower surface and an entire upper surface in order to prevent a portion of the via electrode 42 or the conducting layer 40 and an upper surface of the metal substrate 10 from being oxidized.

At the oxidation insulation step S95, by oxidizing a lower surface portion of the metal substrate 10 in which the oxidation barrier layer 92 is not formed, an oxide layer 94 is formed.

After the oxidation insulation step S95 is performed, the oxidation barrier layer 92 is removed and the soldering step S98 is performed.

As described above, when the oxide layer 94 is formed, at the soldering step S98, if the solder ball 68 is installed to contact with the conducting layer 40 or the via electrode 42, a short circuit between the solder ball 68 and the metal substrate 10 can be prevented.

At the reflow step S99, a reflow process of performing soldering by applying a heat to the solder ball 68 is performed.

As described above, when performing the soldering step S98 and the reflow step S99, at the height adjustment step S90, because the solder ball 68 is guided along a concave portion that is formed while removing a portion of the metal substrate 10, the solder ball 68 can be stably supported and thus soldering can be performed at a more accurate position.

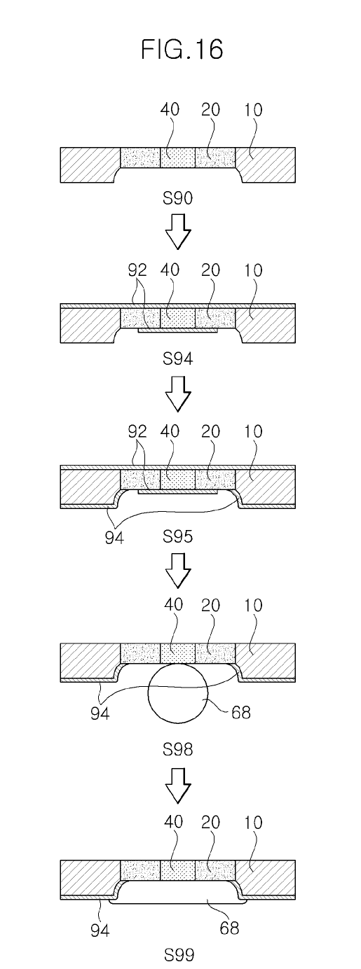

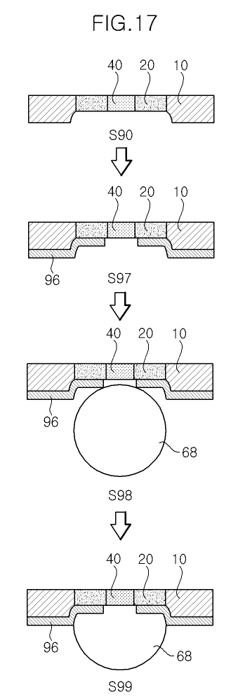

FIG. 15 illustrates a process of performing soldering using a relatively large solder ball 68 of a BGA form, and FIG. 16 illustrates a process of performing soldering using a relatively small solder ball 68 of an LGA form.

As shown in FIG. 17, in a method of manufacturing a metal base package module having a via structure according to an eleventh exemplary embodiment of the present invention, at the height adjustment step S90, after partially removing only a portion of the peripheral metal substrate 10 of a portion in which the metal oxide layer 20 is formed or a portion in which the via 30 is formed without removing an entire surface of a lower end portion of the metal substrate 10 (see FIG. 4), insulation pattern coating step S97, soldering step S98, and reflow step S99 are sequentially further performed.

At the insulation pattern coating step S97, in a portion that is exposed to a lower surface side of the metal substrate 10, by coating an insulation material of an organic material in a predetermined pattern, the insulation layer 96 is formed.

As described above, when the insulation layer 96 is formed, if the solder ball 68 is installed to contact with the conducting layer 40 or the via electrode 42, a short circuit between the solder ball 68 and the metal substrate 10 can be prevented.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing a metal base package having a via structure, the method comprising:
preparing a metal substrate;
forming an oxidation prevention mask pattern in the prepared metal substrate;
forming a metal oxide layer by oxidizing a metal substrate portion that is exposed between the oxidation prevention mask pattern in a predetermined depth;
removing the oxidation prevention mask pattern;
forming a via forming mask pattern on the metal substrate and the metal oxide layer;
forming a via in the metal oxide layer by performing chemical etching in the metal oxide layer in which the via forming mask pattern is not formed;
removing the via forming mask pattern; and
forming a conducting layer with a conductive material at the inside of the formed via.

2. The method of claim 1, further comprising filling a pore of the inside of the via before forming the conducting layer.

3. The method of claim 1, further comprising forming the conducting layer and then installing a solder ball to be connected to the conducting layer of the via.

4. The method of claim 1, further comprising forming the conducting layer and then forming a redistribution to be connected to the conducting layer of the via.

5. The method of claim 1, wherein the oxidation prevention mask pattern is formed in one surface of the metal substrate to expose a portion to form the metal oxide layer.

6. The method of claim 1, wherein a surface opposite to a surface in which the oxidation prevention mask pattern is formed is protected by covering to prevent oxidation using an electrode for performing oxidation, when oxidizing the metal substrate.

7. The method of claim 1, wherein the via forming mask pattern exposes a metal oxide layer of a portion in which the via is to be formed.

8. The method of claim 1, further comprising forming the conducting layer and then removing a lower end portion of the metal substrate to correspond to a thickness of the metal oxide layer.

9. The method of claim 1, further comprising forming the conducting layer and then exposing a conducting layer by partially removing a peripheral metal substrate of a portion in which the metal oxide layer is formed or a portion in which the via is formed.

10. The method of claim 9, further comprising:
exposing the conducting layer and then forming an oxidation barrier layer in a conducting layer portion of a lower surface and an entire upper surface to prevent the conducting layer portion and an upper surface of the metal substrate from being oxidized;
forming an oxide layer by oxidizing a lower surface portion of the metal substrate in which the oxidation barrier layer is not formed and then removing the oxidation barrier layer;
installing a solder ball to contact with the conducting layer that is exposed by removing the metal substrate; and
performing soldering by applying a heat to the solder ball.

11. The method of claim 9, further comprising:
forming an insulation layer by exposing the conducting layer and then coating an insulation material in an entire surface of a lower surface portion of the metal substrate;
installing a solder ball to contact with the conducting layer that is exposed by removing the metal substrate; and
performing soldering by applying a heat to the solder ball.

12. The method of claim 1, further comprising:
forming the oxidation prevention mask pattern only in a lower surface of the metal substrate, and
forming a metal oxide layer in two stages by oxidizing an entire upper surface of the metal substrate and a portion of a lower surface of the metal substrate that are exposed between the oxidation prevention mask pattern.

13. The method of claim 12, further comprising:
forming a via forming mask pattern on the metal oxide layer that is formed at an upper surface side of the metal substrate; and
forming a via by penetrating the metal oxide layer that is formed in two stages by performing chemical etching in the metal oxide layer and then forming a conducting layer.

14. The method of claim 1, further comprising forming a metal oxide layer, forming a via, and forming a conducting layer by oxidizing an entire upper surface of the metal substrate in a state of protecting a lower surface of the metal substrate with an electrode without forming the oxidation prevention mask pattern.

15. The method of claim 1, further comprising:
forming the conducting layer and then performing lapping or etching so that a metal substrate of a lower surface of the metal oxide layer remains in a predetermined thickness; and
forming a redistribution of a lower surface by removing a portion of the metal substrate remaining in the lower surface of the metal oxide layer in a predetermined pattern.

16. The method of claim 1, further comprising forming a metal oxide layer by oxidizing the entire metal substrate without forming the oxidation prevention mask pattern and then forming a via and forming a conducting layer.

17. The method of claim 1, further comprising:
forming the conducting layer and then forming an electrode mask pattern to prevent the metal substrate of a portion in which the conducting layer is formed from being etched;
forming a lower electrode that is connected to the conducting layer by removing the metal substrate of a portion in which the electrode mask pattern is not formed;
forming an insulation layer by filling an insulation material in a portion in which the metal substrate is removed; and
installing a solder ball in a portion in which the lower electrode is formed.

18. The method of claim 1, further comprising forming the oxidation prevention mask pattern to conceal a portion to use as a portion of the via in the metal substrate and forming a portion of the metal substrate as a via electrode and forming a via and forming a conducting layer when forming a metal oxide layer by performing oxidation.

19. The method of claim 18, further comprising:
forming the conducting layer and the via electrode and then forming an electrode mask pattern to prevent the metal substrate of a portion in which the conducting layer and the via electrode are formed from being etched;
forming a lower electrode that is connected to the conducting layer and the via electrode by removing the metal substrate of a portion in which the electrode mask pattern is not formed;
forming an insulation layer by filling an insulation material in a portion in which the metal substrate is removed; and
installing a solder ball in a portion in which the lower electrode is formed.

20. A method of manufacturing a metal base package having a via structure, the method comprising:
preparing a metal substrate;
forming an oxidation prevention mask pattern in a portion to use as a via electrode in the prepared metal substrate;
forming a metal oxide layer by oxidizing an exposed metal substrate portion in which the oxidation prevention mask pattern is not formed in a predetermined depth; and
exposing an unoxidized metal substrate portion by removing the oxidation prevention mask pattern and forming the unoxidized metal substrate portion as a via electrode.

21. The method of claim 20, further comprising forming the via electrode and then installing a solder ball to be connected to the via electrode.

22. The method of claim 20, further comprising forming the via electrode and then forming a redistribution to be connected to the via electrode.

23. The method of claim 20, further comprising forming the via electrode and then removing a lower end portion of a metal substrate to correspond to a thickness of the metal oxide layer.

24. The method of claim 20, further comprising forming the via electrode and then exposing the via electrode by partially removing a peripheral metal substrate of a portion in which the metal oxide layer is formed and a portion in which the via electrode is formed.

25. The method of claim 24, further comprising:
exposing the via electrode and then forming an oxidation barrier layer in a via electrode portion of a lower surface and an entire upper surface to prevent the via electrode portion and an upper surface of the metal substrate from being oxidized;
forming an oxide layer by performing oxidation in a lower surface portion of the metal substrate in which the oxidation barrier layer is not formed and then removing the oxidation barrier layer;
installing a solder ball to contact with a via electrode that is exposed by removing the metal substrate; and
performing soldering by applying a heat to the solder ball.

26. The method of claim 24, further comprising:
forming an insulation layer by exposing the via electrode and then coating an insulation material in an entire surface of a lower surface portion of the metal substrate;
installing a solder ball to contact with a via electrode that is exposed by removing the metal substrate; and
performing soldering by applying a heat to the solder ball.

27. The method of claim 20, further comprising:
forming the via electrode and then performing lapping or etching so that a metal substrate of a lower surface of the metal oxide layer remains in a predetermined thickness; and
forming a redistribution of a lower surface by removing a portion of the metal substrate remaining in the lower surface of the metal oxide layer in a predetermined pattern.

28. The method of claim 20, further comprising:
forming the via electrode and then forming an electrode mask pattern to prevent the metal substrate of a portion in which the via electrode is formed from being etched;
forming a lower electrode that is connected to the via electrode by removing the metal substrate of a portion in which the electrode mask pattern is not formed;
forming an insulation layer by filling an insulation material in a portion in which the metal substrate is removed; and
installing a solder ball in a portion in which the lower electrode is formed.

29. The method of claim 20, further comprising:
forming the via electrode and then forming an electrode mask pattern to prevent the metal substrate of a portion in which the via electrode is formed from being etched;
forming a lower electrode that is connected to the via electrode by removing the metal substrate of a portion in which the electrode mask pattern is not formed;
forming an insulation layer by filling an insulation material in a portion in which the metal substrate is removed; and
installing a solder ball in a portion in which the lower electrode is formed.
